(19) United States
(12) Patent Application Publication
(10) Pub. No.: US 2024/0204009 A1
(43) Pub. Date: Jun. 20, 2024

(54) FILM PACKAGE AND DISPLAY MODULE INCLUDING SAME

(71) Applicant: Samsung Electronics Co., Ltd., Suwon-si (KR)

(72) Inventors: Seunghyun Cho, Suwon-si (KR); Jaemin Jung, Suwon-si (KR); Jeongkyu Ha, Suwon-si (KR)

(21) Appl. No.: 18/237,013

(22) Filed: Aug. 23, 2023

(30) Foreign Application Priority Data
Dec. 19, 2022 (KR) 10-2022-0178364

(51) Int. Cl. H01L 27/12

(52) U.S. Cl. CPC H01L 27/1244

(57) ABSTRACT

A film package includes: a film substrate having a first side surface and a second side surface opposing each other in a first direction, each of the first side surface and the second side surface extending in a second direction perpendicular to the first direction; at least one semiconductor chip disposed on the film substrate and extending lengthwise in the first direction; input terminals arranged on the film substrate along the first side surface, output terminals arranged on the film substrate along the second side surface, and wirings formed on the film substrate and electrically connecting the input terminals and the output terminals to the at least one semiconductor chip; and a protective layer covering the wirings on the film substrate.

### CROSS-REFERENCE TO RELATED APPLICATION(S)

This application claims the benefit under 35 USC 119(a) of Korean Patent Application No. 10-2022-0178364 filed on Dec. 19, 2022 in the Korean Intellectual Property Office, the entire disclosure of which is incorporated herein by reference for all purposes.

### BACKGROUND

Aspects of the present inventive concept relate to a film package and a display module.

In order to cope with the recent trend for miniaturization, thinning, and lightening of electronic products, a chip on film (hereinafter referred to as COF) package technology using a flexible film substrate has been proposed. In the COF package technology, a semiconductor chip is mounted on a film substrate using a flip chip bonding method and may be connected to an external device by a wiring line. Such a COF package may be applied to a panel of a portable terminal device such as a cellular phone or a PDA, a laptop computer, or a display device.

### SUMMARY

Example embodiments provide a film package having an increased distance between output terminals.

Example embodiments provide a display module in which a bezel area of a display panel adjacent to output terminals of a film package is significantly reduced.

According to example embodiments, a film package includes a film substrate having a front surface and a rear surface opposing each other, a first side surface and a second side surface opposing each other in a first direction, and a third side surface and a fourth side surface opposing each other in a second direction, intersecting the first direction; a first semiconductor chip and a second semiconductor chip disposed on the front surface of the film substrate and spaced apart in the second direction; a front protective layer extending lengthwise in the second direction to cover at least a portion of the front surface of the film substrate and having openings in which the first and second semiconductor chips are disposed; a rear protective layer extending lengthwise in the second direction to cover at least a portion of the rear surface of the film substrate; and a plurality of wiring patterns. The plurality of wiring patterns include a front wiring positioned between the front protective layer and the front surface of the film substrate, electrically connected to the first and second semiconductor chips, and including first wiring lines extending from the first semiconductor chip toward at least one of the first and second side surfaces and second wiring lines extending from the second semiconductor chip toward at least one of the first and second side surfaces, a backside wiring positioned between the rear protective layer and the rear surface of the film substrate, electrically connected to at least one of the first and second semiconductor chips, and including third wiring lines extending from one of the first and second semiconductor chips toward at least one of the first and second side surfaces, input terminals adjacent to each other and exposed from the front protective layer on an end of the front wiring adjacent to the first side surface, and output terminals adjacent to each other and exposed from the front protective layer on an end of the front wiring adjacent to the second side surface.

According to example embodiments, a film package includes: a film substrate having a first side surface and a second side surface opposing each other in a first direction, each of the first side surface and the second side surface extending in a second direction perpendicular to the first direction; at least one semiconductor chip disposed on the film substrate and extending lengthwise in the first direction; input terminals arranged on the film substrate along the first side surface, output terminals arranged on the film substrate along the second side surface, and wirings formed on the film substrate and electrically connecting the input terminals and the output terminals to the at least one semiconductor chip; and a protective layer covering the wirings on the film substrate.

According to example embodiments, a film package includes a film substrate having a first side surface and a second side surface opposing each other in a first direction and extending in a second direction perpendicular to the first direction; at least a first semiconductor chip disposed on the film substrate and having first edges opposing each other in the first direction and second edges opposing each other in the second direction; input terminals arranged on the film substrate to be adjacent to the first side surface; output terminals arranged on the film substrate to be adjacent to the second side surface; and wirings on the film substrate, each wiring extending from one of the second edges of the first semiconductor chip to one terminal of the input terminals and the output terminals.

According to example embodiments, a film package includes a film substrate having a first side surface and a second side surface opposing each other in a first direction, and a third side surface and a fourth side surface opposing each other in a second direction, intersecting the first direction; at least one semiconductor chip disposed on the film substrate, each semiconductor chip of the at least one semiconductor chip having first edges opposing each other in the first direction and second edges opposing each other in the second direction; input terminals arranged on the film substrate to be adjacent to the first side surface; output terminals arranged on the film substrate to be adjacent to the second side surface; and wirings electrically connecting the at least one semiconductor chip to the input terminals and the output terminals. In a plan view, a distance from any of the second edges of any semiconductor chip of the at least one semiconductor chip to the third side surface or the fourth side surface is greater than a distance from any of the first edges of any semiconductor chip of the at least one semiconductor chip to the first side surface or the second side surface.

According to example embodiments, a display module includes a film package unit including a film substrate having a first side surface and a second side surface opposing each other in a first direction, at least one semiconductor chip disposed on the film substrate, input terminals disposed on the film substrate to be adjacent to the first side surface, output terminals disposed on the film substrate to be adjacent to the second side surface, and wirings electrically connecting the at least one semiconductor chip to the input terminals and the output terminals, on the film substrate; a display panel disposed adjacent to the first side surface of the film package unit and including panel connection wires electrically connected to the output terminals; and a driving printed circuit board disposed adjacent to the second side surface of the film package unit and including driving connection wires electrically connected to the input terminals. A distance between adjacent output terminals of the film package unit is substantially the same as a distance between adjacent panel connection wires exposed at an edge of the display panel.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1A is a plan view schematically illustrating the front of the film package according to an example embodiment, and FIG. 1B is a bottom view schematically illustrating the rear of the film package of FIG. 1A;

FIG. 2A is a cross-sectional view taken along line I-I′ of FIGS. 1A and 1B, and FIG. 2B is a cross-sectional view taken along line II-II′ of FIGS. 1A and 1B;

FIG. 3A is a plan view schematically illustrating the front of the film package according to an example embodiment, and FIG. 3B is a bottom view schematically illustrating the rear of the film package of FIG. 3A;

FIG. 4A is a plan view schematically illustrating the front of the film package according to an example embodiment, and FIG. 4B is a bottom view schematically illustrating the rear of the film package of FIG. 4A;

FIG. 5A is a plan view schematically illustrating the front of the film package according to an example embodiment, and FIG. 5B is a bottom view schematically illustrating the rear of the film package of FIG. 5A;

FIG. 6A is a front layout of a base film including film packages according to an example embodiment, and FIG. 6B is a rear layout of the base film of FIG. 6A; and

FIG. 7A is a perspective view schematically illustrating a display module including film package units according to an example embodiment, and FIG. 7B is a cross-sectional view illustrating a state of use of the display module of FIG. 7A.

### DETAILED DESCRIPTION

Hereinafter, example embodiments will be described with reference to the accompanying drawings. Items described in the singular herein may be provided in plural, as can be seen, for example, in the drawings. Thus, the description of a single item that is provided in plural may apply to the remaining plurality of items.

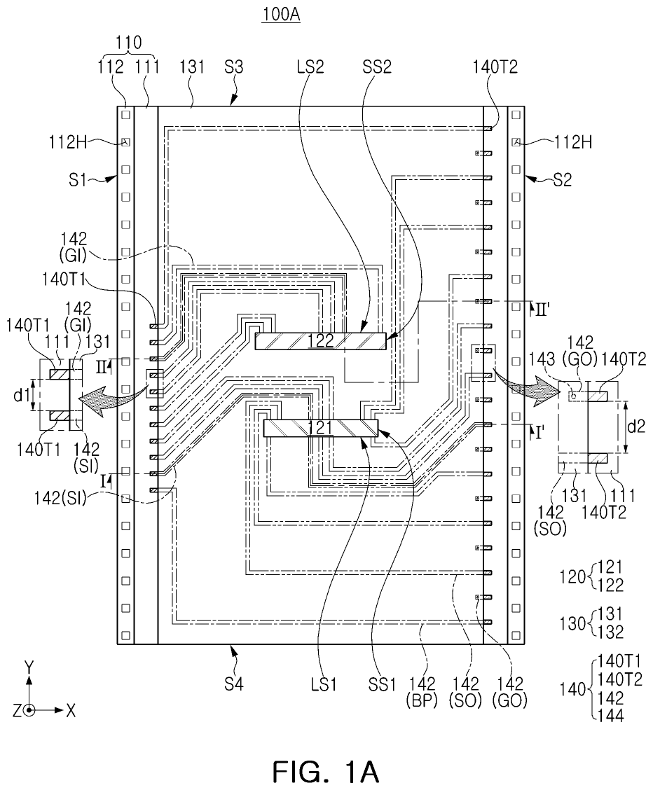

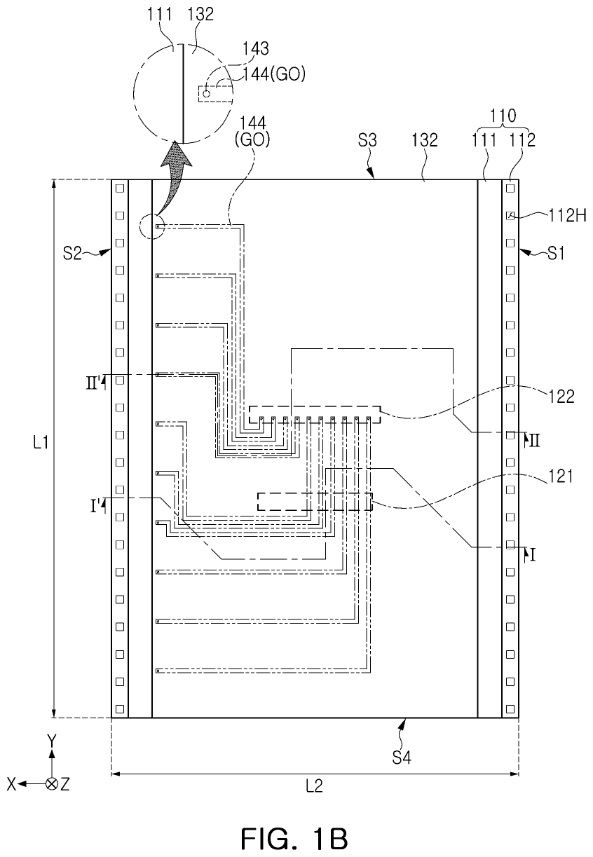

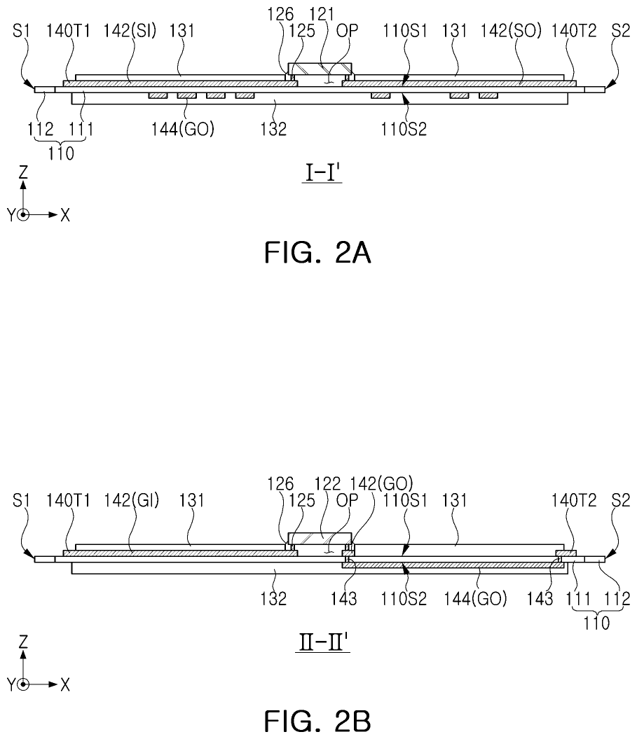

FIG. 1A is a plan view schematically illustrating the front of a film package 100A according to an example embodiment, and FIG. 1B is a bottom view schematically illustrating the rear of the film package 100A of FIG. 1A. FIG. 2A is a cross-sectional view taken along line I-I′ of FIGS. 1A and 1B, and FIG. 2B is a cross-sectional view taken along line II-II′ of FIGS. 1A and 1B. The opening OP and the underfill layer 126 illustrated in FIGS. 2A and 2B are omitted from FIG. 1A for convenience of description.

Referring to FIGS. 1A to 2B, a semiconductor package 100A according to an example embodiment may include a film substrate 110, at least one semiconductor chip 120, and a plurality of wiring patterns 140. According to an example embodiment, the semiconductor package 100A may further include a protective layer 130 covering at least a portion of the plurality of wiring patterns 140.

A wiring pattern, as described herein, includes one or more conductive components formed at a given vertical level (and which may therefore be formed or a homogenous material layer in a single process step). For example, an individual wiring line extending between and electrically connected between two end points, and formed at a particular vertical level may be described as a wiring pattern. An individual wiring line at a particular vertical level may also be described herein as a trace. In addition, a group of such wiring lines may also be described as a wiring pattern. The plurality of wiring patterns 140 discussed herein refers in general to any group of wiring patterns from all of the wiring patterns formed on the film substrate 110. Individual wiring patterns (e.g., an individual wiring line), may be part of sets or groups of wiring patterns. The term “wiring” may be used to describe a particular wiring line, and may also be used to describe a set of conductive components directly electrically connected in order to electrically connect two end points. The term “wire connection” may be used to describe a set of conductive components directly connected in series to electrically connect two end points. Wiring patterns, wiring lines, wiring, and wire connections, may all be described in the singular to refer to an individual component, or maybe used in plural (e.g., using the terms “set” or “group” or “plurality” to describe a plurality of such components. As used herein, components described as being “electrically connected” are configured such that an electrical signal can be transferred from one component to the other (although such electrical signal may be attenuated in strength as it is transferred and may be selectively transferred). Moreover, components that are “directly electrically connected” share a common electrical node through electrical connections by one or more conductors, such as, for example, wires, pads, internal electrical lines, through vias, etc. As such, directly electrically connected components do not include components electrically connected through active elements, such as transistors or diodes.

A plurality of wiring patterns may include a set of wiring patterns grouped together. For example, a set of wiring patterns may follow a similar path. For example, adjacent wiring patterns, as viewed from a plan view, may include portions that follow along a path, for example to include parallel segments.

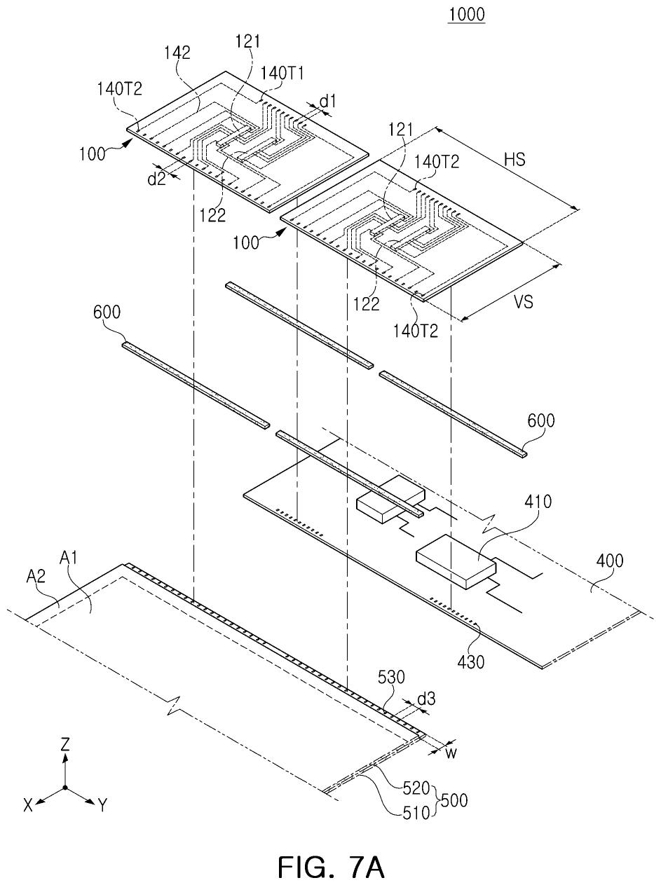

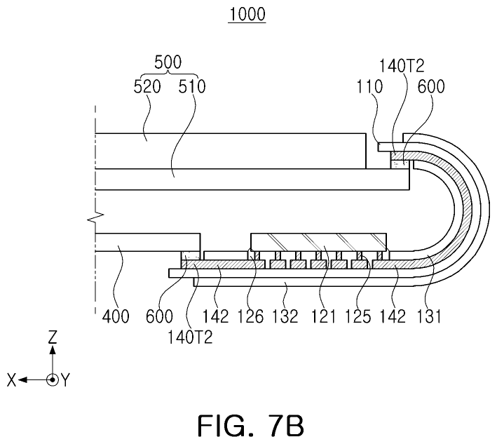

By arranging the input terminals (140T1) and the output terminals (140T2) in the longitudinal direction (e.g., Y-direction) of the film substrate 110, a desired level of distances between the input terminals (140T1) and between the output terminals 140T2 may be secured without design limitations. As a result, the area in which the input terminals 140T1 and the output terminals 140T2 are redistributed in the display module ('1000′ in FIG. 7A) may be significantly reduced. For example, as illustrated in FIG. 7A, according to an example embodiment of the present inventive concept, the distance d2 between the output terminals 140T2 is formed equal to the distance d3 between the panel connection wires 530, so that in the display panel (500), a bezel area formed on at least one side may be significantly reduced, and a 4-sided bezel-less display panel may be implemented.

The film substrate 110 has a front surface (‘110S1’ in FIG. 2A) and a rear surface (‘110S2’ in FIG. 2A) opposing each other in the vertical direction (Z-direction), and side surfaces S1, S2, S3 and S4 opposing each other in the horizontal direction (X or Y-direction), respectively. For example, the film substrate 110 may have a first side surface (S1) and a second side surface (S2) opposing each other in a first direction (e.g., X-direction), and a third side surface S3 and a fourth side surface S4 opposing each other in a second direction (e.g., Y-direction) intersecting the first direction. The first direction may be perpendicular to the second direction. The front surface 110S1 of the film substrate 110 may be a chip mounting surface on which at least one semiconductor chip 120 (e.g., a semiconductor chip 121 and/or a semiconductor chip 122) is disposed, and the rear surface 110S2 of the film substrate 110 may be defined as a surface opposite thereto. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

The film substrate 110 may elongate (e.g., extend lengthwise) in one direction, for example, in a second direction (Y-direction). In this case, the first length L1 of the first side surface S1 and the second side surface S2 may be longer than the second length L2 of the third side surface S3 and the fourth side surface S4. An item, layer, or portion of an item or layer described as extending “lengthwise” or having a “lengthwise direction” in a particular direction has a length in the particular direction and a width perpendicular to that direction, where the length is greater than the width. The term “elongate” as used in this specification refers to an item extending lengthwise. The term “longitudinal” refers to a lengthwise direction. The term “extension direction” also is used herein to have the same meaning as “lengthwise direction.” The first side surface S1 and the second side surface S2 may be formed with a length capable of arranging the output terminals 140T2 at a desired interval d2. The third side surface S3 and the fourth side surface S4 may be determined according to specifications of the base film. For example, the first length L1 in the second direction (Y-direction) may be in a range of about 150 mm to about 250 mm, about 180 mm to about 220 mm, or about 190 mm to about 210 mm. The second length L2 in the first direction (X-direction) may range from about 20 mm to about 80 mm, from about 25 mm to about 75 mm, and from about 30 mm to about 70 mm. Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range. Also, the first length L1 and the second length L2 are not limited to the aforementioned numerical ranges. According to an example embodiment of the present inventive concept, the input terminals 140T1 and the output terminals 140T2 are disposed (e.g., arranged) in the longitudinal direction of the film substrate 110, so that the input terminals 140T1 and the output terminals (140T2) may be disposed at desired intervals, for example in a row extending in the second direction (Y-direction). Therefore, according to some embodiments, it is possible to design the arrangement interval of the input terminals 140T1 and the output terminals 140T2 without changing the specifications of the base film or changing the process equipment. In some embodiments, as can be seen for example in FIGS. 1A and 1B, a plurality of semiconductor chips, such as semiconductor chip 121 and semiconductor chip 122, may be arranged in the second direction (Y-direction) to be horizontally spaced apart from each other in the second direction, which is the longitudinal direction of the of the film substrate 110. In addition, as described in more detail below, each semiconductor chip (e.g., semiconductor chip 121 or semiconductor chip 122) may extend lengthwise in a different direction from the longitudinal direction of the film substrate 110, and may extend lengthwise in a direction perpendicular to the longitudinal direction of the film substrate 110W.

The film substrate 110 may include a first region 111 and a second region 112 disposed on opposite sides of the first region 111. The film substrate 110 may be described as including two second regions 112 (e.g., one on one side of the first region 111 and another on the opposite side of the first region 111). The first region 111 is a region in which at least one semiconductor chip 120 is mounted and a plurality of wiring patterns 140 are formed, and the second region 112 is disposed on opposite sides of the first region 111. The second region 112 may be a perforation (PF) area. In the second region 112, through-holes 112H penetrating the film substrate 110 may be disposed or arranged in an extension direction of the film substrate 110, for example, in a second direction (Y-direction). The through-holes 112H may be sprocket holes for controlling the reeling and releasing of the film substrate 110 or the base film (‘110P’ in FIG. 7A). The second region(s) 112 may also be described as a sprocket hole region(s) or perforation region(s).

The film substrate 110 may be a flexible film including or formed of polyimide, which is a material having a high coefficient of thermal expansion and durability, but the material of the film substrate 110 is not limited thereto. For example, the film substrate 110 may be formed of a synthetic resin such as epoxy resin, acrylic, polyether nitrile, polyether sulfone, polyethylene terephthalate, polyethylene naphthalate, or the like.

At least one semiconductor chip 120 may be disposed on the front surface 110S1 of the film substrate 110. Each semiconductor chip of the at least one semiconductor chip 120 may elongate in a direction perpendicular to the longitudinal direction of the film substrate 110. For example, each semiconductor chip of the at least one semiconductor chip 120 may elongate in the first direction (X-direction). In this case, each semiconductor chip 121 and 122 of the at least one semiconductor chip 120 may have first edges (SS1 for semiconductor chip 121 or SS2 for semiconductor chip 122) opposing each other in a first direction (X-direction) and second edges (LS1 for semiconductor chip 121 or LS2 for semiconductor chip 122) opposing each other in a second direction (Y-direction), and lengths of the second edges LS1 or LS2 may be longer than lengths of the first edges SS1 or SS2. The first edges SS1 or SS2 face the first side surface S1 and the second side surface S2 in the first direction (X-direction), respectively, and the second edges LS1 or LS2 may face the third side surface S3 and the fourth side surface S4 in the second direction (Y-direction), respectively. According to aspects of the present inventive concept, since the both input terminals 140T1 and the output terminals 140T2 are disposed or arranged in the longitudinal direction (e.g., Y-direction) of the film substrate 110, an arrangement direction of the input terminals 140T1 and the output terminals 140T2 may be perpendicular to the extending direction of the second edges LS1 or LS2. In addition, in a plan view, the separation distance from the fourth side surface S4 to the second edge LS1 closest to the fourth side surface S4, and the separation distance from the third side surface S3 to the second edge LS2 closest to the third side surface S2, in the second direction (Y-direction) may each be greater than the separation distance between each first edge SS1 or SS2 to the respective first side surface S1 or the second side surface S2 that each first edge SS1 or SS2 faces.

The at least one semiconductor chip 120 may be a display driving chip (DDI) used to drive a display. The at least one semiconductor chip 120 may include at least one of a source driving chip and a gate driving chip. The source driving chip may generate an image signal using the data signal transmitted from the timing controller and output the image signal to a display panel. Source inputs (or source input patterns) and source outputs (or source output patterns) as described herein refer to inputs and outputs from a source driving chip. The gate driving chip may output a scan signal including an on/off signal of a transistor to a display panel. Gate inputs (or gate input patterns) and gate outputs (or gate output patterns) as described herein refer to inputs and outputs from a gate driving chip. Each semiconductor chip of the at least one semiconductor chip 120 may be mounted on the film substrate 110 using a flip chip bonding method. Each semiconductor chip of the at least one semiconductor chip 120 may be physically and electrically connected to the plurality of wiring patterns 140 through conductive terminals such as connection bumps 125. The connection bump 125 may be formed using a conductive material such as aluminum (Al), copper (Cu), nickel (Ni), tungsten (W), platinum (Pt), or gold (Au). An underfill layer 126 sealing the connection bumps 125 may be formed between each semiconductor chip of the at least one semiconductor chip 120 and the film substrate 110. The underfill layer 126 may be formed using, for example, an insulating resin such as epoxy resin. The at least one semiconductor chip 120 may be provided in more or less numbers than illustrated in the drawing (e.g., a single chip, or 3 or more chips).

According to example embodiments, the at least one semiconductor chip 120 may include a plurality of semiconductor chips, such as semiconductor chip 121 and semiconductor chip 122. For example, the at least one semiconductor chip 120 may include a first semiconductor chip 121 and a second semiconductor chip disposed on the front surface 110S1 of the film substrate 110 to be spaced apart in a second direction (Y-direction). For example, the first semiconductor chip 121 may be a source driving chip and the second semiconductor chip 122 may be a gate driving chip, but the embodiments are not limited thereto. In a plan view, the separation distance from the second edges LS1 of the first semiconductor chip 121 to the third side surface S3 or the fourth side surface S4 may be greater than the separation distance from the first edges SS1 of the first semiconductor chip 121 to the first side surface S1 or the second side surface S2. In a plan view, the separation distance from the second edges LS2 of the second semiconductor chip 122 to the third side surface S3 or the fourth side surface S4 may be greater than the separation distance from the second edges SS2 of the second semiconductor chip 122 to the first side surface S1 or the second side surface S2. Also, the separation distance between the first semiconductor chip 121 and the second semiconductor chip 122 may be less than the separation distance from the second edges LS1 or LS2 to the third side surface S3 or the fourth side surface S4.

The protective layer 130 may be disposed on the surface of the film substrate 110 to protect the plurality of wiring patterns 140 from external physical and/or chemical damage. The protective layer 130 may be respectively disposed on the front surface 110S1 and the rear surface 110S2 of the film substrate 110. The protective layer 130 may include a front protective layer 131 extending lengthwise in the second direction (Y-direction) to cover at least a portion of the front surface 110S1 of the film substrate 110, and a rear protective layer 132 extending lengthwise in the second direction (Y-direction) to cover at least a portion of the rear surface 110S2 of the film substrate 110. The front protective layer 131 may have at least one opening OP in which at the least one semiconductor chip 120 is accommodated. Each semiconductor chip of the at least one semiconductor chip 120 may be disposed in a respective opening of the at least one opening OP. The protective layer 130 may be formed of an insulating material, for example, solder resist or dry film resist.

The plurality of wiring patterns 140 may include input terminals 140T1, output terminals 140T2, and wirings (e.g., wiring lines) 142 and 144. The plurality of wiring patterns 140 may extend on the film substrate 110 to electrically connect an external device (e.g., a printed circuit board, a display panel, etc.) and at least one semiconductor chip 120.

The input terminals 140T1 and the output terminals 140T2 may be respectively disposed on opposite sides of the film substrate 110. The input terminals 140T1 and the output terminals 140T2 may be electrically connected to the at least one semiconductor chip 120 through wirings 142 and 144. The input terminals 140T1 and the output terminals 140T2 may be part of the wirings 142 and 144 exposed from the protective layer 130. In a plan view, the input terminals 140T1 and the output terminals 140T2 may not overlap the protective layer 130. For example, the input terminals 140T1 may be disposed on the film substrate 110 to be adjacent to the first side surface S1. The input terminals 140T1 may be ends of the front wiring 142 disposed along the first side surface S1. For example, the output terminals 140T2 may be disposed on the film substrate 110 to be adjacent to the second side surface S2. The output terminals 140T2 may be ends of the front wiring 142 disposed along the second side surface S2.

According to an example embodiment of the present inventive concept, the input terminals 140T1 and the output terminals 140T2 are disposed at desired pitches, and the desired pitches of the output terminals 140T2 may be increased without changing specifications of the base film or changing process equipment. Accordingly, the distance d2 between the adjacent output terminals 140T2 may be greater than the distance d1 between the adjacent input terminals 140T1. The distance d1 between the input terminals 140T1 may be determined by the distance between driving connection wires (‘430’ in FIG. 7A) of the driving printed circuit board, which will be described later. The input terminals 140T1 may have a constant pitch in the second direction (Y-direction). The distance d2 between the output terminals 140T2 may be determined by the spacing of panel connection wires (‘530’ in FIG. 7A) of the display panel, which will be described later. The output terminals 140T2 may have a constant pitch in the second direction (Y-direction). The distance d1 between the input terminals 140T1 may be in a range from about 1 μm to about 30 μm, from about 5 μm to about 25 μm, and from about 10 μm to about 20 μm. The distance d2 between the output terminals 140T2 may be in a range from about 10 μm to about 100 μm, from about 20 μm to about 80 μm, and from about 30 μm to about 60 μm. The distance d1 between the input terminals 140T1 and the distance d2 between the output terminals 140T2 are not limited to the above numerical range.

Wirings 142 and 144 may extend from the long side (e.g., the second edges LS1 or LS2) of each semiconductor chip of the at least one semiconductor chip 120 to input terminals 140T1 and output terminals 140T2. The wirings 142 and 144 may include front wirings 142 extending on the front surface 110S1 of the film substrate 110 and rear wirings 144 extending on the rear surface 110S2. On one surface (e.g., front surface or rear surface), the front wirings 142 or the rear wirings 144 among the at least one semiconductor chip 120 may extend from the long sides of the at least one semiconductor chip 120 toward the first side surface S1 and the second side surface S2 of the film substrate 110 on which the input terminals 140T1 and the output terminals 140T2 are disposed. For example, the front wiring 142, positioned between the front protective layer 131 and the front surface 110S1 of the film substrate 110, may be electrically connected to the first semiconductor chip 121 and the second semiconductor chip 122, and may extend toward at least one side surface from among the first side surface S1 and the second side surface S2. For example, the rear wiring 144, positioned between the rear protective layer 132 and the rear surface 110S2 of the film substrate 110, may be electrically connected to the first semiconductor chip 121 and the second semiconductor chip 122, and may extend toward at least one side surface from among the first side surface S1 and the second side surface S2. The front wiring 142 and the rear wiring 144 may be electrically connected to each other through a vias 143 penetrating the film substrate 110. The vias 143 may be conductive through vias, formed for example of a metal such as copper (Cu) or aluminum (Al). In the drawings, the input terminals 140T1 and the output terminals 140T2 are both illustrated as ends of the front wiring 142, but the embodiments are not limited thereto. Depending on the example embodiment, at least some of the input terminals 140T1 and the output terminals 140T2 may be ends of the rear wiring 144.

The wirings 142 may include a source input pattern SI and a source output pattern SO connecting the source driving chip and the input terminals 140T1 and output terminals 140T2, respectively, and a gate input pattern GI and a gate output pattern GO connecting the gate driving chip and input terminals 140T1 and output terminals 140T2, respectively. The wirings 142 may further include bypass patterns BP connecting at least some of the input terminals 140T1 and at least some of the output terminals 140T2. The bypass pattern BP may directly connect the input terminals 140T1 and the output terminals 140T2 without passing through at least one semiconductor chip 120.

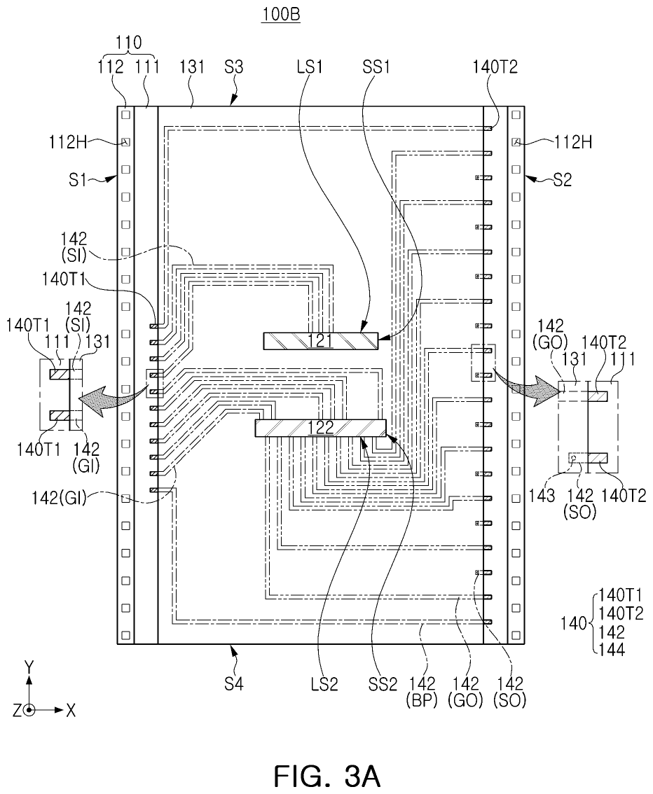

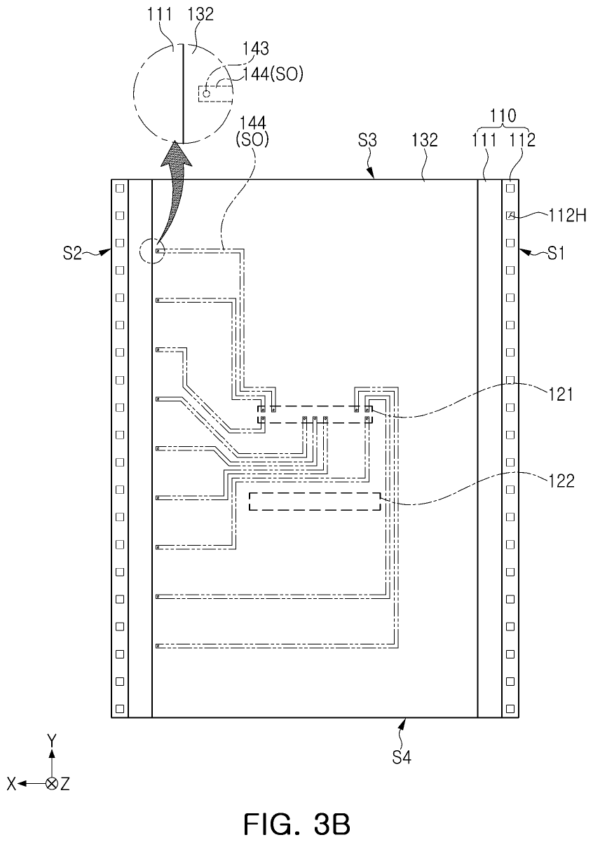

At least some of the source input pattern SI, source output pattern SO, gate input pattern GI, and gate output pattern GO, are electrically connected to input terminals 140T1 or output terminals 140T2 via the rear wiring 144. As a result, the density of the front wiring 142 on the front surface 110S1 of the film substrate 110 may be reduced, and the degree of design freedom may be increased. In this embodiment, the front wiring 142 may include a source input pattern SI connecting the first semiconductor chip 121 to the input terminals 140T1, a source output pattern SO connecting the first semiconductor chip 121 to the output terminals 140T2, a gate input pattern GI connecting the second semiconductor chip 122 to the input terminals 140T1, and a gate output pattern GO connecting the second semiconductor chip 122 to the output terminals 140T2. The rear wiring 144 may include only the gate output pattern GO connecting the second semiconductor chip 122 to the output terminals 140T2. For example, the second semiconductor chip 122 may be electrically connected to the output terminals 140T2 through the gate output pattern GO of the front wiring 142 and the rear wiring 144. Depending on the example embodiment, the rear wiring 144 may include other patterns (see FIGS. 3A to 5B).

FIG. 3A is a plan view schematically illustrating the front of the film package (100B) according to an example embodiment, FIG. 3B is a bottom view schematically illustrating the rear of the film package of FIG. 3A.

Referring to FIGS. 3A and 3B, a semiconductor package 100B according to an example embodiment may have the same or similar features as those described with reference to FIGS. 1A to 2B except that the rear surface wiring 144 includes the source output pattern SO.

In this embodiment, the front wiring 142 may include a source input pattern SI connecting the first semiconductor chip 121 to the input terminals 140T1, a source output pattern SO connecting the first semiconductor chip 121 to the output terminals 140T2, a gate input pattern GI connecting the second semiconductor chip 122 to the input terminals 140T1, and a gate output pattern GO connecting the second semiconductor chip 122 to the output terminals 140T2. The rear wiring 144 may include only the source output pattern GO connecting the first semiconductor chip 121 to the output terminals 140T2. For example, the first semiconductor chip 121 may be electrically connected to the output terminals 140T2 through the source output pattern SO of the front wiring 142 and the rear wiring 144. In the drawing, the input terminals 140T1 and the output terminals 140T2 are both illustrated as ends of the front wiring 142, but depending on the example embodiment, at least some of the input terminals 140T1 and the output terminals 140T2 may be ends of the rear wiring 144.

In this manner, by bypassing at least some of the source input pattern SI, the source output pattern SO, the gate input pattern GI, and the gate output pattern GO to the rear side 110S2 of the film substrate 110 using the rear wiring 144, the density of the front wiring 142 may be reduced, and the degree of freedom in the design of the front wiring 142 may be increased.

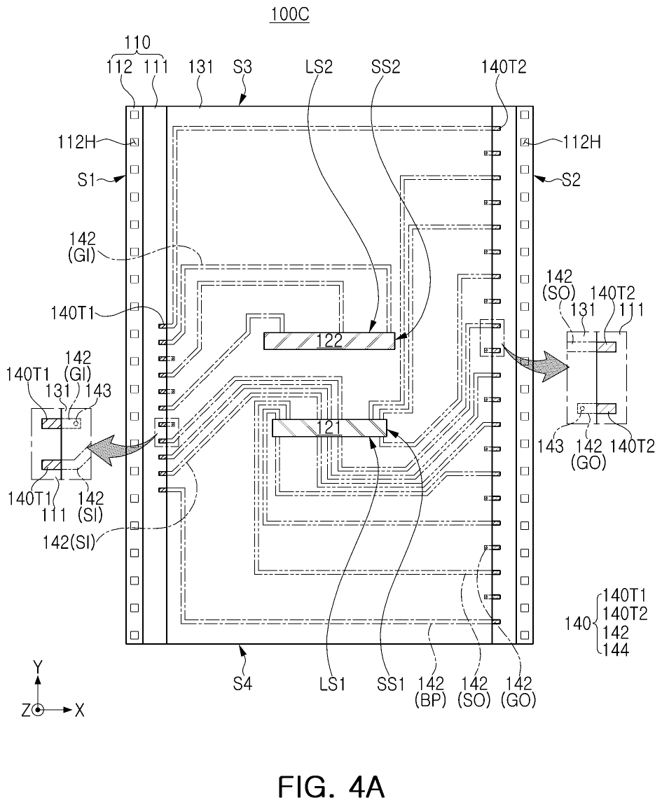

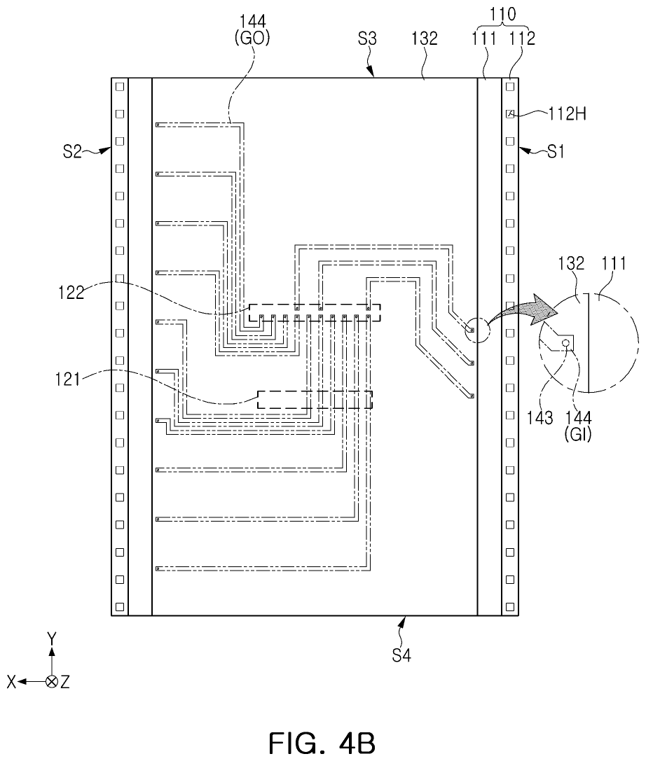

FIG. 4A is a plan view schematically illustrating the front of the film package (100C) according to an example embodiment, FIG. 4B is a bottom view schematically illustrating the rear of the film package (100C) of FIG. 4A.

Referring to FIGS. 4A and 4B, a semiconductor package 100C according to an example embodiment may have the same or similar features as those described with reference to FIGS. 1A to 3B, except that the rear wiring 144 includes the gate input pattern GI and the gate output pattern GO.

In this embodiment, the front wiring 142 may include a source input pattern SI connecting the first semiconductor chip 121 to the input terminals 140T1, a source output pattern SO connecting the first semiconductor chip 121 to the output terminals 140T2, a gate input pattern GI connecting the second semiconductor chip 122 to the input terminals 140T1, and a gate output pattern GO connecting the second semiconductor chip 122 to the output terminals 140T2. The rear wiring 144 may include a gate input pattern GI connecting the second semiconductor chip 122 to the input terminals 140T1, and a gate output pattern GO connecting the second semiconductor chip 122 to the output terminals 140T2. For example, the second semiconductor chip 122 may be electrically connected to the input terminals 140T1 and the output terminals 140T2 through the gate input pattern GI and gate output pattern GO of the front wiring 142 and the rear wiring 144. In the drawing, both the input terminals 140T1 and the output terminals 140T2 are illustrated as ends of the front wiring 142, but according to embodiments, at least some of the input terminals 140T1 and the output terminals 140T2 may be the end of the rear wiring 144.

In this manner, by bypassing at least some of the source input pattern SI, the source output pattern SO, the gate input pattern GI, and the gate output pattern GO to the rear side (110S2) of the film substrate 110 using the rear wiring 144, the density of the front wiring 142 may be reduced, and the degree of freedom in the design of the front wiring 142 may be increased.

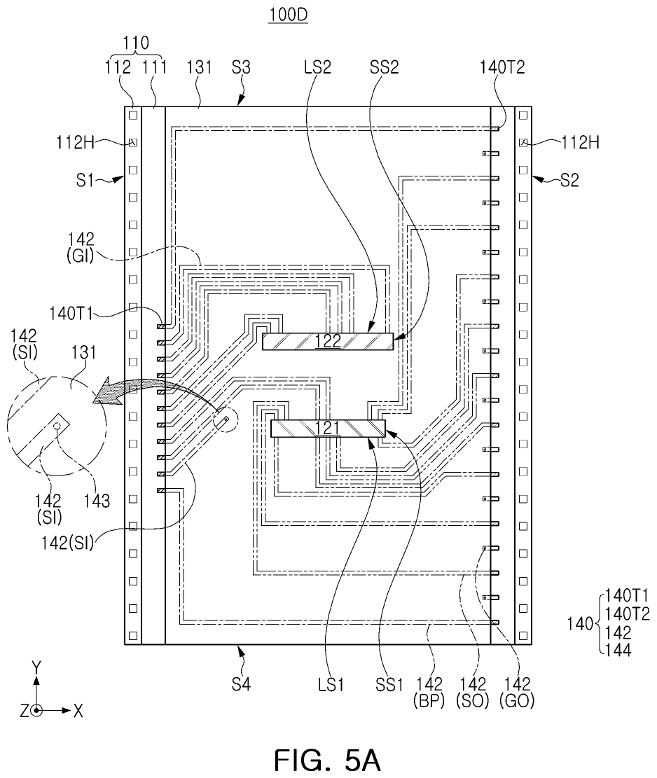

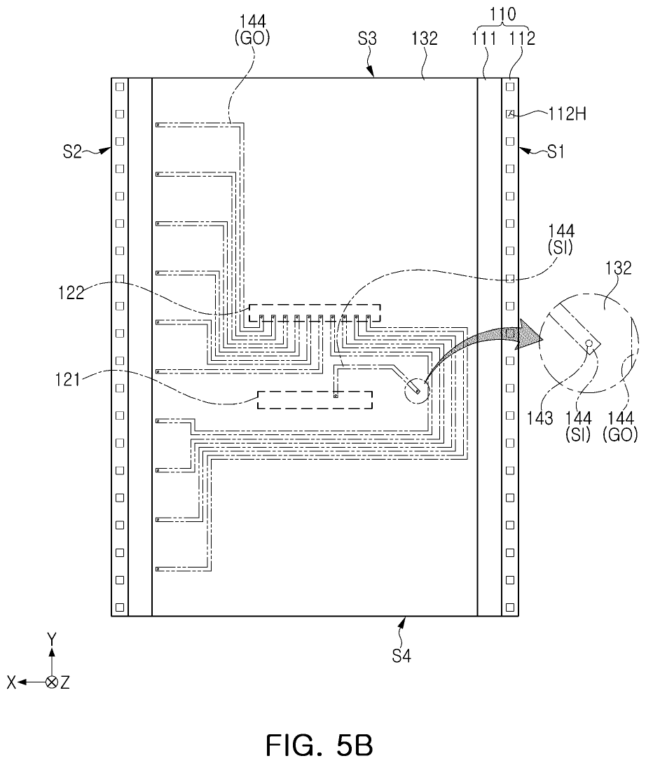

FIG. 5A is a plan view schematically illustrating the front of the film package (100D) according to an example embodiment, FIG. 5B is a bottom view schematically illustrating the rear of the film package (100D) of FIG. 5A.

Referring to FIGS. 5A and 5B, a semiconductor package 100D according to an example embodiment may have the same or similar features as those described with reference to FIGS. 1A to 4B, except that the rear wiring 144 includes the source input pattern SI and the gate output pattern GO.

In this embodiment, the front wiring 142 may include a source input pattern SI connecting the first semiconductor chip 121 to the input terminals 140T1, a source output pattern SO connecting the first semiconductor chip 121 to the output terminals 140T2, a gate input pattern GI connecting the second semiconductor chip 122 to the input terminals 140T1, and a gate output pattern GO connecting the second semiconductor chip 122 to the output terminals 140T2. The rear wiring 144 may include a gate input pattern GI connecting the second semiconductor chip 122 to the input terminals 140T1, and a gate output pattern GO connecting the second semiconductor chip 122 to the output terminals 140T2. For example, the first semiconductor chip 121 may be electrically connected to the input terminals 140T1 through the source input pattern SI of the front wiring 142 and the rear wiring 144. The second semiconductor chip 122 may be electrically connected to the output terminals 140T2 through the gate output pattern GO of the front wiring 142 and the rear wiring 144. In the drawing, the input terminals 140T1 and the output terminals 140T2 are both illustrated as ends of the front wiring 142, but depending on the example embodiment, at least some of the input terminals 140T1 and the output terminals 140T2 may be ends of the rear wiring 144.

In this manner, by bypassing at least some of the source input pattern SI, the source output pattern SO, the gate input pattern GI, and the gate output pattern GO to the rear side (110S2) of the film substrate 110 using the rear wiring 144, the density of the front wiring 142 may be reduced and the degree of freedom in the design of the front wiring 142 may increase.

The combination of the front wiring 142 and the rear wiring 144 for the source input pattern SI, the source output pattern SO, the gate input pattern GI, and the gate output pattern GO is not limited to the above-described embodiments, and may be modified in various manners.

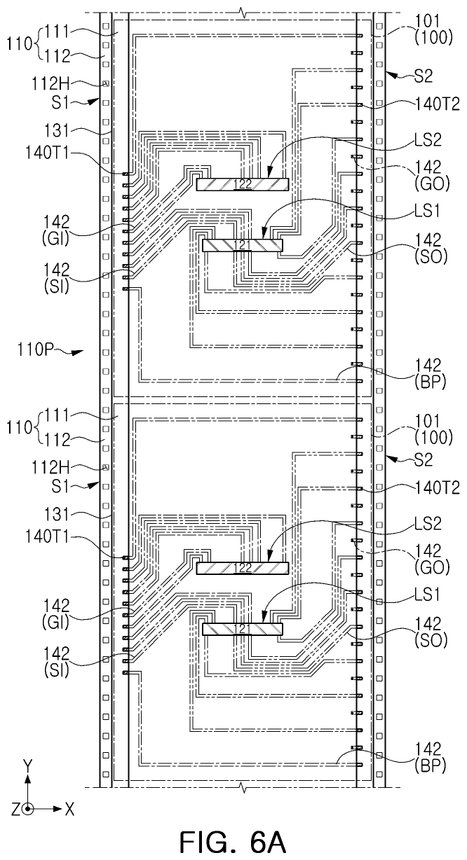

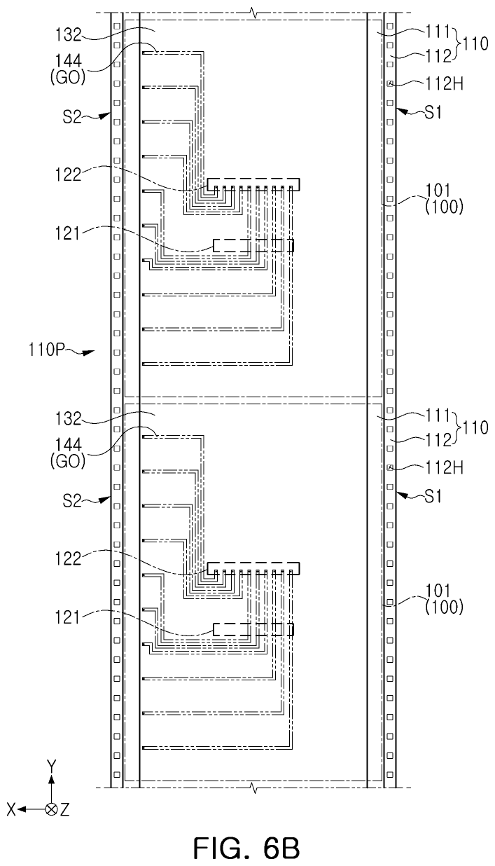

FIG. 6A is a front layout of a base film 110P including film packages according to an example embodiment, and FIG. 6B is a rear layout of the base film 110P of FIG. 6A.

Referring to FIGS. 6A and 6B, the base film 110P may elongate in a second direction (Y-direction) and may include a first region 111 and a second region 112. The first region 111 may be referred to as a circuit region of the base film 110P. The second region 112 may be referred to as a perforation (PF) region 112 disposed on both side ends of the base film 110P.

The base film 110P may include a plurality of film package units 100 defined by the cutting line 101. In this case, the cutting line 101 may be a virtual dividing line. The first semiconductor chip 121, the second semiconductor chip 122, the input terminals 140T1, the output terminals 140T2, and the wirings 142 and 144 constituting the film package unit 100 may be disposed within the first region 111. The film package unit 100 may elongate in a second direction (Y-direction) identical to the extension direction of the base film 110P.

The first semiconductor chip 121 and the second semiconductor chip 122 may be disposed on the front surface of the base film 110P to be spaced apart from each other in the second direction (Y-direction). The first semiconductor chip 121 and the second semiconductor chip 122 may be connected to the front wiring 142 in a flip-chip method. For example, the first semiconductor chips 121 may each be a source driving chip, and the second semiconductor chips 122 may each be a gate driving chip, but the embodiments are not limited thereto.

Input terminals 140T1 and output terminals 140T2 may be respectively disposed on opposite sides of the base film 110P. The input terminals 140T1 and the output terminals 140T2 may be electrically connected to the first semiconductor chip 121 and the second semiconductor chip 122 through wirings 142 and 144. The input terminals 140T1 and the output terminals 140T2 may be ends of the front wiring 142 exposed from the protective layer 130. For example, the input terminals 140T1 may be adjacent to the first side surface S1 and the output terminals 140T2 may be adjacent to the second side surface S2.

The front wiring 142 and the rear wiring 144 may extend from the long sides (e.g., the second edges LS1 or LS2) of the first semiconductor chip 121 and the second semiconductor chip 122 to the input terminals 140T1 and the output terminals 140T2. At least some of the input terminals 140T1 and the output terminals 140T2 may be connected to the semiconductor chips 121 and 122 through the rear wiring 144. The front protective layer 131 and the rear protective layer 132 may be disposed on opposite surfaces of the base film 110P, respectively, and may cover the front wiring 142 and the rear wiring 144, respectively.

The base film 110P may be wound using through-holes 112H formed in the second region 112. The through-holes 112H may be sprocket holes for controlling reeling and releasing of the base film 110P.

FIG. 7A is a perspective view schematically illustrating a display module 1000 including film package units 100 according to an example embodiment, and FIG. 7B is a cross-sectional view illustrating a state of use of the display module 1000 of FIG. 7A.

Referring to FIGS. 7A and 7B, the package module 1000 may include a plurality of film package units 100, a driving printed circuit board 400, and a display panel 500.

The film package units 100 may include a display driver IC (DDI). For example, heterogeneous semiconductor chips may be mounted on the film package units 100. For example, the first semiconductor chip 121 may be a source driving chip, and the second semiconductor chip 122 may be a gate driving chip. The film package units 100, also described as film packages, may be connected to the driving printed circuit board 400 and the display panel 500, respectively. Input terminals 140T1 and output terminals 140T2 of the film package units 100 may be electrically connected to the driving connection wire 430 of the driving printed circuit board 400 and the panel connection wire 530 of the display panel 500, respectively. The film package units 100 may receive signals output from the driving printed circuit board 400 and transmit the same to the display panel 500.

As illustrated in FIG. 7A, the display module 1000 may include a plurality of film package units 100. For example, the display panel 500 is intended to provide a large-area screen such as a television, or in the case of supporting a relatively high resolution, the driving printed circuit board 400 and the display panel 500 may be interconnected through a plurality of film packages 100. A plurality of film package units 100 may be disposed on one side of the display panel 500, but the embodiments are not limited thereto. Depending on the example embodiment, the plurality of film package units 100 may be disposed on two or more sides of the display panel 500.

Depending on the example embodiment, the display module 1000 may include one film package unit 100. For example, when the display panel 500 is intended to provide a screen of a small area such as a mobile phone or supports a relatively low resolution, the driving printed circuit board 400 and the display panel 500 may be interconnected through one film package unit 100.

The input terminals 140T1 and the output terminals 140T2 are connected to the driving connection wire 430 of the driving printed circuit board 400 and the panel of the display panel 500 by an anisotropic conductive layer 600. Each may be connected to the wire 530. The anisotropic conductive layer 600 may be an anisotropic conductive film or an anisotropic conductive paste in which conductive particles are dispersed in an insulating adhesive layer. The anisotropic conductive layer 600 is interposed between the facing electrodes, and electricity may be conducted only in the direction in which the electrodes face each other (Z-direction), and may have anisotropic electrical characteristics insulated from neighboring electrodes in a direction (Y-direction) between the electrodes.

One or more driving circuit chips 410 capable of simultaneously or sequentially applying power and signals to the film package units 100 may be mounted on the driving printed circuit board 400.

The display panel 500 may be, for example, a liquid crystal display (LCD) panel, a light emitting diode (LED) panel, an organic LED (OLED) panel, a plasma display panel (PDP), or the like. The display panel 500 may include a transparent substrate 510, an image area 520 formed on the transparent substrate 510, and a panel connection wire 530. The transparent substrate 510 may be, for example, a glass substrate or a transparent flexible substrate. The image area 520 may have a display area A1 displaying an image and a peripheral area A2 applying a driving signal to the display area A1. A plurality of pixels in the display area A1 may be connected to a plurality of corresponding panel connection wires 530, and may be operated according to the signal provided by the display driving chip (DDI) mounted on the film package units 100.

According to some embodiments of the present inventive concept, the distance d2 between the output terminals 140T2 of the film package units 100 is formed equal to the distance d3 of the panel connection wires 530 of the display panel 500, and the width W of a bezel area formed on at least one side of the display panel 500 may be significantly reduced, and a four-sided bezel-less display panel may be implemented.

As set forth above, according to example embodiments, wiring patterns connecting input/output terminals and semiconductor chips may extend in a predetermined direction, thereby providing a film package in which a distance between the output terminals is increased.

In addition, according to example embodiments, since the output terminals of the film package and the panel connection wires of the display panel have the same distance, a display module having a significantly reduced bezel area may be provided.

While example embodiments have been illustrated and described above, it will be apparent to those skilled in the art that modifications and variations could be made without departing from the scope of the present invention as defined by the appended claims.

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Spatially relative terms, such as “beneath,” “below,” “lower,” “above,” “upper,” “top,” “bottom,” “front,” “rear,” and the like, may be used herein for ease of description to describe positional relationships, such as illustrated in the figures, for example. It will be understood that the spatially relative terms encompass different orientations of the device in addition to the orientation depicted in the figures.

1. A film package comprising:
a film substrate having a front surface and a rear surface opposing each other, a first side surface and a second side surface opposing each other in a first direction, and a third side surface and a fourth side surface opposing each other in a second direction, intersecting the first direction;
a first semiconductor chip and a second semiconductor chip disposed on the front surface of the film substrate and spaced apart in the second direction;
a front protective layer extending lengthwise in the second direction to cover at least a portion of the front surface of the film substrate and having openings in which the first and second semiconductor chips are disposed;
a rear protective layer extending lengthwise in the second direction to cover at least a portion of the rear surface of the film substrate; and
a plurality of wiring patterns including,
a front wiring positioned between the front protective layer and the front surface of the film substrate, electrically connected to the first and second semiconductor chips, and including first wiring lines extending from the first semiconductor chip toward at least one of the first and second side surfaces and second wiring lines extending from the second semiconductor chip toward at least one of the first and second side surfaces, ,
a backside wiring positioned between the rear protective layer and the rear surface of the film substrate, electrically connected to at least one of the first and second semiconductor chips, and including third wiring lines extending from one of the first and second semiconductor chips toward at least one of the first and second side surfaces,
input terminals adjacent to each other and exposed from the front protective layer on an end of the front wiring adjacent to the first side surface, and
output terminals adjacent to each other and exposed from the front protective layer on an end of the front wiring adjacent to the second side surface.

2. The film package of claim 1, wherein a distance between the output terminals adjacent to each other is greater than a distance between the input terminals adjacent to each other.

3. The film package of claim 2, wherein:
the distance between the input terminals is in a range from about 5 μm to about 25 μm, and
the distance between the output terminals is in a range from about 30 μm to about 60 μm.

4. The film package of claim 1, wherein each of the first side surface and the second side surface has a first length, and each of the third side surface and the fourth side surface has a second length, wherein the first length is greater than the second length.

5. The film package of claim 4, wherein:
the first length is in a range from about 180 mm to about 220 mm, and
the second length is in a range from about 30 mm to about 70 mm.

6. The film package of claim 1, wherein:
each semiconductor chip of the first and second semiconductor chips has first edges opposing each other in the first direction and second edges opposing each other in the second direction, and
a length of each of the second edges is greater than a length of each of the first edges.

7. The film package of claim 6, wherein the second edges of the first semiconductor chip face the third side surface and the fourth side surface, respectively, and the second edges of the second semiconductor chip face the third side surface and the fourth side surface, respectively.

8. The film package of claim 6, wherein an arrangement direction of the input terminals and an arrangement direction of the output terminals are each perpendicular to an extension direction of the second edges.

9. The film package of claim 1, wherein the front wiring and the backside wiring are electrically connected to each other through vias penetrating through the film substrate.

10. The film package of claim 1, wherein the plurality of wiring patterns further include a bypass pattern directly connecting at least some of the input terminals and at least some of the output terminals.

11. The film package of claim 1, wherein the first and second semiconductor chips include a source driving chip and a gate driving chip, respectively.

12. The film package of claim 1, wherein the front wiring and the backside wiring include at least one of a source input pattern connecting the first semiconductor chip to the input terminals, a source output pattern connecting the first semiconductor chip to the output terminals, a gate input pattern connecting the second semiconductor chip to the input terminals, and a gate output pattern connecting the second semiconductor chip to the output terminals.

13. The film package of claim 1, wherein the film substrate includes a first region in which the plurality of wiring patterns are disposed and which extends in the second direction, and a second region disposed on opposite sides of the first region adjacent to the first side surface and the second side surface,
wherein the second region has through-holes arranged in the second direction.

14. A film package comprising:
a film substrate having a first side surface and a second side surface opposing each other in a first direction, each of the first side surface and the second side surface extending in a second direction perpendicular to the first direction;
at least one semiconductor chip disposed on the film substrate and extending lengthwise in the first direction;
input terminals arranged on the film substrate along the first side surface, output terminals arranged on the film substrate along the second side surface, and wirings formed on the film substrate and electrically connecting the input terminals and the output terminals to the at least one semiconductor chip; and
a protective layer covering the wirings on the film substrate.

15. The film package of claim 14, wherein:
a length of the film substrate in the second direction is in a range from about 180 mm to about 220 mm, and
a length of the film substrate in the first direction is in a range from about 30 mm to about 70 mm.

16. The film package of claim 14, wherein in a plan view, the input terminals and the output terminals do not overlap with the protective layer.

17. The film package of claim 14, wherein the wirings include a front wiring extending on a front surface of the film substrate on which the at least one semiconductor chip is disposed, and a rear wiring extending on a rear surface opposite to the front surface.

18. The film package of claim 17, wherein in a plan view, the front wiring extends from one or more sides, extending in the first direction, of the at least one semiconductor chip to the input terminals and the output terminals, and rear wiring extends from one or more sides, extending in the first direction, of at least a first semiconductor chip to at least one of: the input terminals and the output terminals.

19. A film package comprising:
a film substrate having a first side surface and a second side surface opposing each other in a first direction and extending in a second direction perpendicular to the first direction;
at least a first semiconductor chip disposed on the film substrate and having first edges opposing each other in the first direction and second edges opposing each other in the second direction;
input terminals arranged on the film substrate to be adjacent to the first side surface;
output terminals arranged on the film substrate to be adjacent to the second side surface; and
wirings on the film substrate, each wiring extending from one of the second edges of the first semiconductor chip to one terminal of the input terminals and the output terminals.

20. The film package of claim 19, wherein a length of each of the second edges is greater than a length of each of the first edges.

21-30. (canceled)
